(19) United States
(12) Patent Application Publication
(10) Pub. No.: US 2010/0218806 A1
(43) Pub. Date: Sep. 2, 2010

(54) CONCENTRATED SOLAR SYSTEM

(75) Inventors: Ra'ed Arab, Ottawa (CA); William Masek, Ottawa (CA)

Correspondence Address: Miltons IP/p.i., 225 Metcalfe Street, Suite 700, Ottawa, ON, K2P 1P9, CA

(73) Assignee: QUADRA SOLAR CORPORATION, Ottawa, ON (CA)

(21) Appl. No.: 12/676,748

(22) PCT Filed: Sep. 5, 2008
(86) PCT No.: PCT/CA08/01572

§ 371 Date: Mar. 5, 2010

(30) Foreign Application Priority Data
Sep. 7, 2007 (CA) 2602872

(51) Int. Cl. H01L 31/042; F28D 15/00

(52) U.S. Cl. 136/246; 136/259; 165/104.33

(57) ABSTRACT

There is provided a concentrating solar collector in the shape of an inverted truncated pyramid (collector) with light reflective surfaces on the inside. The collector includes a large top opening which is pointed towards the sun collecting the sun rays. A high-concentration photovoltaic solar cell is placed at the narrow end of the collector. The light is concentrated onto the solar cell, which generates electricity from the concentrated solar light. The collector is made of, but not limited to, an inflatable lightweight reflective film, balloon filled with helium, glass, plastic or metal. The reflective surface inside the collector is obtained using inexpensive mirror coating which is applied to clear glass or plastic. A cooling system is used for keeping the concentrated photovoltaic solar cell at or close to a fixed temperature to maintain the cell at its highest operating efficiency of power generation.

### BACKGROUND OF THE INVENTION

The present invention generally relates to concentrated solar systems, concentrating solar light and energy and using a collector in the shape of truncated symmetrical inverted pyramid that concentrates light onto the solar cell positioned at its bottom. The plurality of said collectors is movably mounted on the rotating pipes and arranged into the solar energy generating array. The motion of array components is aimed at effectively capturing the sun's rays and concentrating them onto the solar cells.

Photovoltaic technology is the most promising, alternative energy source, creating electricity with no pollution and no noise. Photovoltaic conversion is useful for several reasons. Conversion from sunlight to electricity is direct, so that bulky mechanical generating systems are unnecessary. The modular structure of the photovoltaic arrays makes them highly scalable, easy to set up and allows adaptation to the site characteristics.

A high-concentrating PV system can potentially generate power at a lower cost than flat plate PV systems. The application of high-concentration solar cells technology allows a significant increase in the amount of energy collected by solar arrays per unit area. However, to make it possible, more complicated reflecting techniques involving the use of an expensive, lenses based system are usually required. The present invention is targeted at full realization of the benefits of high-concentrating PV technology without utilizing expensive optical equipment.

The present invention was developed in response to concerns of the future of global power supplies caused by the constraints in fossil fuels as sources of energy and the ever-increasing demand for electricity. Solar concentrated energy systems are an inexhaustible source of power, which can provide much of the world's future energy requirements. The purpose of this invention is to design a low-cost, easy to implement concentrated solar power generation system based on photovoltaic technology and being capable of producing a high efficiency energy return.

Solar energy can be harvested via either thermal or photovoltaic methods to generate electricity. The thermal solution is not applicable to a majority of the industrialized countries climates. Photovoltaic (PV) solutions are best suited for colder climates as it only requires sun light. On the contrary to thermal solutions, PV efficiency is enhanced under cooler temperatures. Cost has been the biggest stumbling block in making PV use widespread. Moreover, existing PV cell panel technologies offer very low efficiencies between 5 to 15%, only fueling the debate that solar technologies require massive areas of land to become a major contributor of power to the grid.

New ultra-efficient PV cells are being developed by companies like Spectrolab or Emcore using High Concentrated Photovoltaic (HCPV) cell technology. Efficiencies of 40.7% have been reached and foreseeing further increases in efficiency to 50% over the coming years, making solar power comparable in cost to current grid supplied electricity. Under 500-sun concentration, for example, one square centimeter of HCPV solar cell area produces the same electricity as 500 cm2 would without concentration. The use of concentration (e.g., lenses or mirrors), therefore enables the replacement of the more expensive semiconductor area with cheaper materials. The use of concentration, however, requires that the module use a dual-axis tracking system, in addition to providing an efficient heat removal mechanism. Still, the savings in the semiconductor area and the higher output due to the use of the higher cell efficiency make the use of High-Concentration Photovoltaic (HCPV) modules with Multi-Junction cells more economical.

### SUMMARY OF THE INVENTION

The concentrated solar photovoltaic system of the present invention utilizes HCPV Multi-Junctions cells to achieve the following targets:
The highest solar efficiency system on the market.
Lowest cost per solar watt coupled with low maintenance and long life.
Not only Dual-Axis, but a Triple-Axis solar tracking system offering the widest tracking angle in the industry.
Most compact and therefore most efficient use of land in the industry.
Most practical solar system to deploy in large scale deployments
Most environmental solar solution with little to no impact on the land
Safer than using parabolic dish reflectors or lenses, which have been known to start grass fires when accidentally pointed in the wrong direction.

In accordance with one aspect of the present invention, there is provided a concentrating solar collector in the shape of an inverted truncated pyramid (hereafter referred to as “collector”) with a light reflective (mirror-like) surface of the inside walls, with the large top opening of the collector pointed toward the sun concentrates the sun's light as it is reflected through the larger opening of the collector to its narrow end. A high-concentration photovoltaic solar cell (hereafter referred to as “solar cell”) is placed at the narrow end of the collector. The light is concentrated onto the solar cell, which generates electricity from the concentrated solar light. The collector is made of material that could hold its shape such as, but not limited to, an inflatable lightweight reflective film (e.g. balloon filled with helium), glass, plastic or metal which takes the shape of an inverted pyramid. The reflective surface inside the collector is obtained using inexpensive mirror coating which is applied to the clear glass or plastic or using reflective surface of metal. A cooling subsystem is used for keeping the concentrated photovoltaic solar cells at or as close to a fixed temperature to maintain the cell at its highest operating efficiency of power generation.

In one embodiment of the invention, a complete Concentrating Solar Photovoltaic System is provided. A collector is mounted, via the collector-base, on to a horizontal pipe that rotates about its own axis (hereafter referred to as “collector-bearing pipe”). Many collectors are mounted on a single collector-bearing pipe. Collector-bearing pipe is perpendicularly connected at its front and back to a front and rear pipes (hereafter referred to as “supporting-pipes”). Collector-bearing pipes rotate 180 degrees: 90 degrees in each direction from a predetermined center position. An array of Collector-bearing pipes is interconnected via the supporting-pipes that extend from one end of the array to the other. The combination of collector-bearing pipes and supporting-pipes make up a solar plane (hereafter referred to as “collector-plane”). Collector-bearing and supporting pipes are positioned horizontally in relation to the ground, or tilted towards the sun's azimuth to obtain a maximal tracking angle during the low-sun sunrise/sunset hours. The collector-plane is mounted on vertical pipes (hereafter referred to as “vertical-pipes”) at each of its corners. Vertical-pipes can be stationary or move up and down. The movable components of the system are mechanically and electronically controlled.

A triple-axis sun tracking system offers tracking along x, y and z axis. A complete system is comprised of multiple rows of collector subsystems oscillating along a 180 degree trajectory (x-axis) and attached to bearing-pipes, which rotate about their own axes (y-axis) and are supported by vertical-pipes that move up and down (z-axis). Collectors tilt front and back (front being the side of the assembly facing the azimuth) along the bearing-pipe that holds them and from left to right across the longitudinal axis of the said pipe. The semi-circle trajectory of collectors' motion relative to the bearing pipe, up to 90 degrees from their upright position, is acquired by electro-mechanical means. The left and right motion is driven by the rotation of the collector-bearing pipes about their own axes. The vertical pipes that hold collector-bearing pipes are shifted up and down by electro-mechanical means.

By the above means, the main components of the system shift their position to attain a complete triple-axis sun tracking, which constitutes a major advantage of the system of the present invention over the conventional dual-axis technique. The same system can also be used as only a dual-axis sun tracking system when using stationary vertical pipes.

Collectors track the sun on two or three axes, to keep solar light rays at a perpendicular angle with the surface of the collector top opening to concentrate the sun's energy at the solar cells. A full sun tracking range of up to 180° from sun rise to sun set is achieved by a combination of oscillating collectors, rotating collector-bearing pipes and the stationary or moving inclination of the collector-plane towards azimuth via the raising and lowering of vertical-pipes of the assembly.

The energy output of the system is proportional to the efficiency of the HCPV solar cell used by the array of collectors.

The collector subsystem is less expensive than standard lenses or parabolic dish collectors. Most system components will be fabricated from low-cost materials and using conventional manufacturing processes. The system is estimated to be highly durable and have low operation and maintenance costs. Unlike standard panels made fully of expensive silicone, the system minimizes silicon consumption by utilizing small-size concentrated photovoltaic cells.

The solar concentration method of the present invention can be adjusted to different concentration levels by controlling the ratio of collector's top opening to its bottom one.

The modular arrangement allows arrays to be installed quickly and in any required configuration or size. The system is highly scalable making it possible to deploy from one to hundreds of sub-arrays.

The invention is adaptable for large-scale arrays used for grid-connected applications and for small-size residential applications. For residential installations, the collector can be designed as a roof-top solar panel, where one panel is made up of adjacent small collectors. Solar concentration at a nano-scale can also be achieved using the method of the present invention.

An elevated version of one embodiment of the present invention is erected at a sufficient height above ground will allow for the full use of the land beneath for agricultural and other purposes, which minimizes the overall footprint. A well spaced out collector-bearing pipes, permits the vast majority of the sunrays to reach the ground below. This translates into a considerable reduction of any environmental land impact of the system when compared to using standard solar panels.

The system is fire safe as opposed to the existing HCPV systems using parabolic mirrors or lenses, which have caused fires when accidentally pointed in the wrong direction.

The system can be implemented using the light-trapping method that allows restricting the escaping reflectance via total internal reflection at the collector opening. The light-trapping method is an alternative to sun tracking.

### BRIEF DESCRIPTION OF THE FIGURES

FIG. 1 illustrates a collector light concentration—side view.

FIG. 2 illustrates a side view, a 3-D view and a top view of a collector.

FIG. 3 illustrates a plane side view—elevated upright.

FIG. 4 illustrates a plane side view—elevated tilted.

FIG. 5 illustrates a plane side view—fixed above ground.

FIG. 6a illustrates a collector-plane—top view in square configuration.

FIG. 6b illustrates a collector-plane—top view in square configuration, compact layout.

FIG. 7 illustrates a collector-plane—top view in star configuration.

FIG. 8 illustrates a collector base assembly—side view.

FIG. 9 illustrates a cooling subsystem—top view and side view which is mounted on semi-circle gear.

FIG. 10 illustrates a bearing pipe assembly.

FIG. 11 illustrates a support pipe mechanism—long cross section view.

FIG. 12 illustrates a support pipe mechanism—round cross section view.

FIG. 13 illustrates a 3D view of the system.

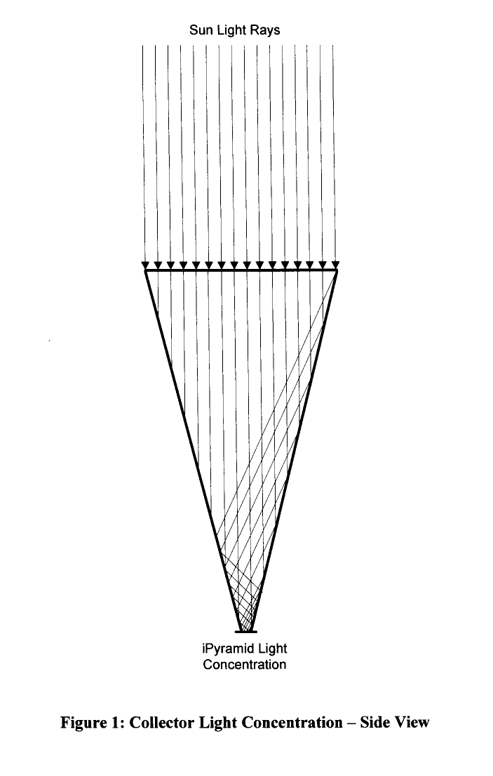

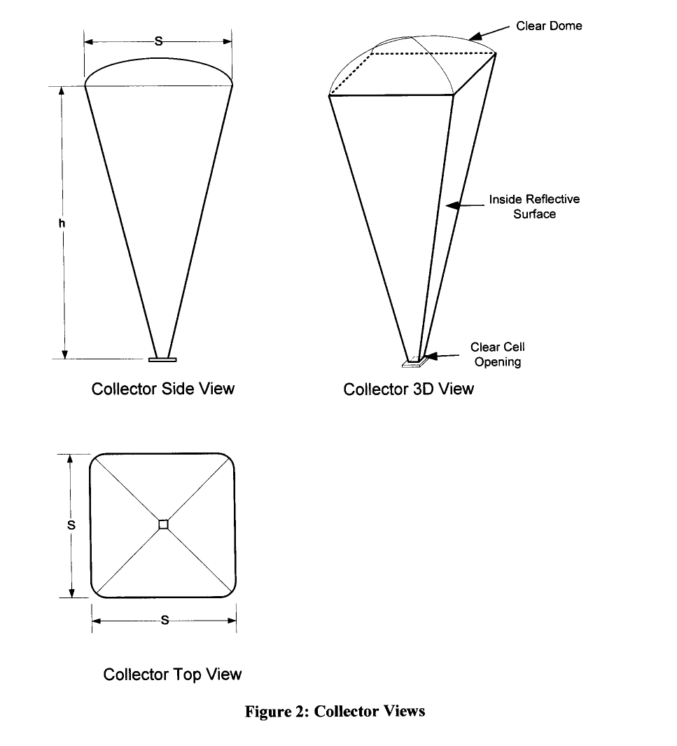

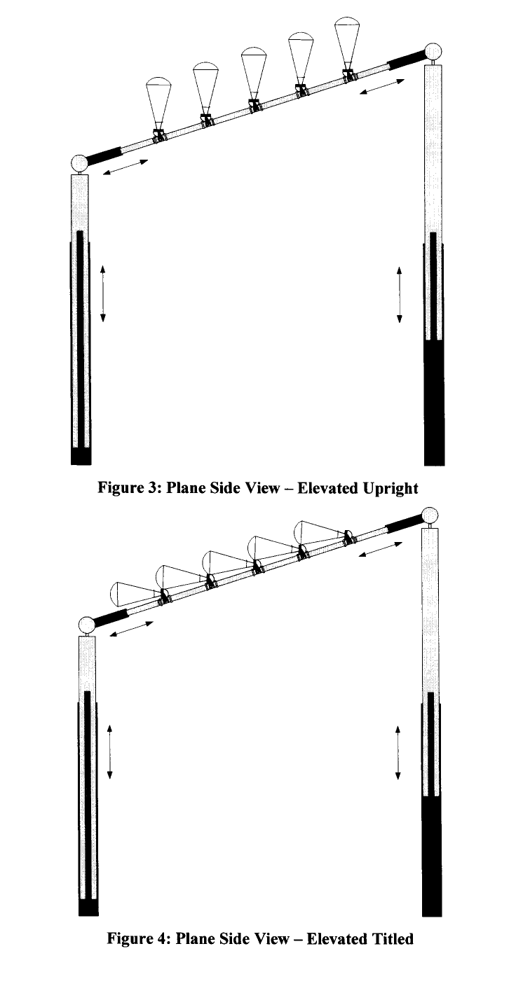

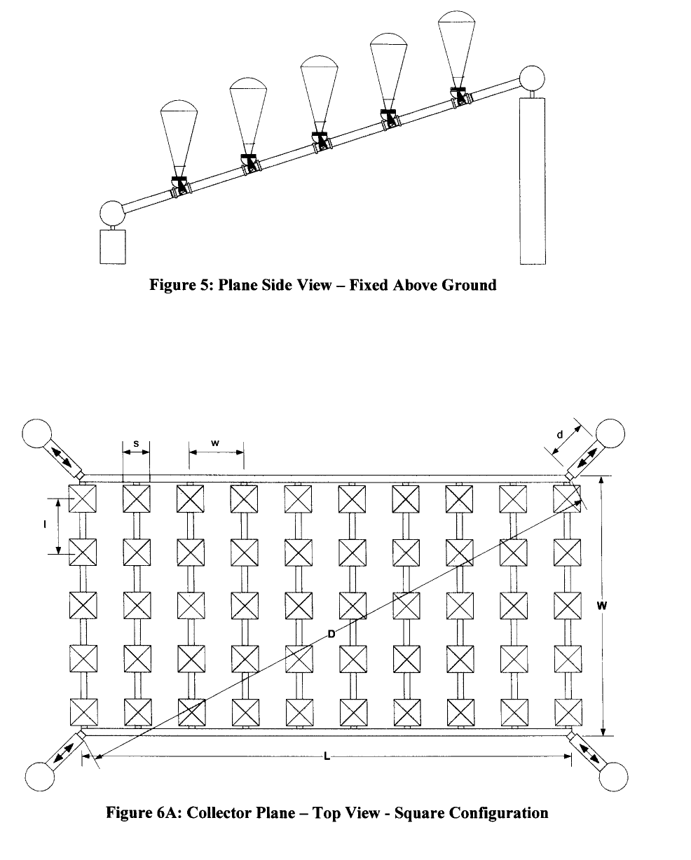

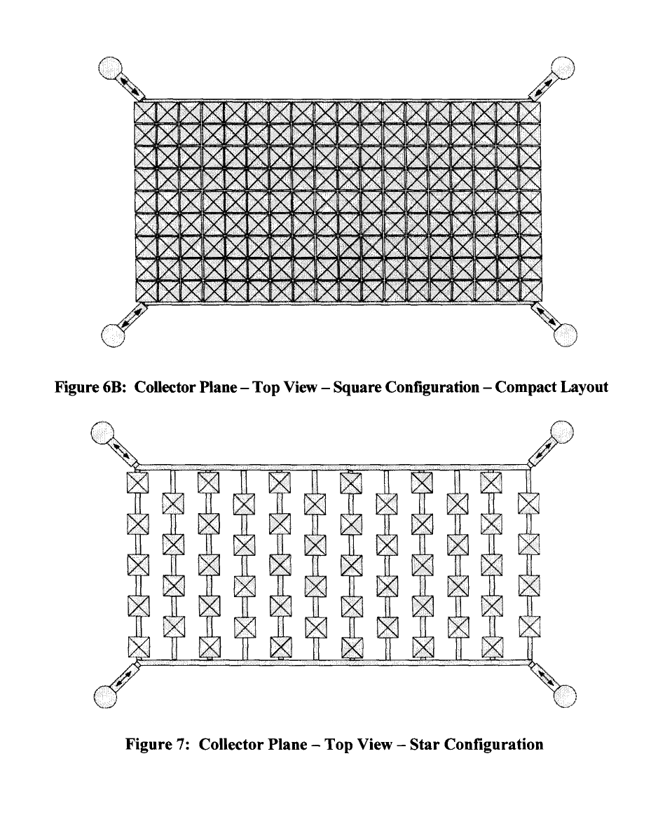

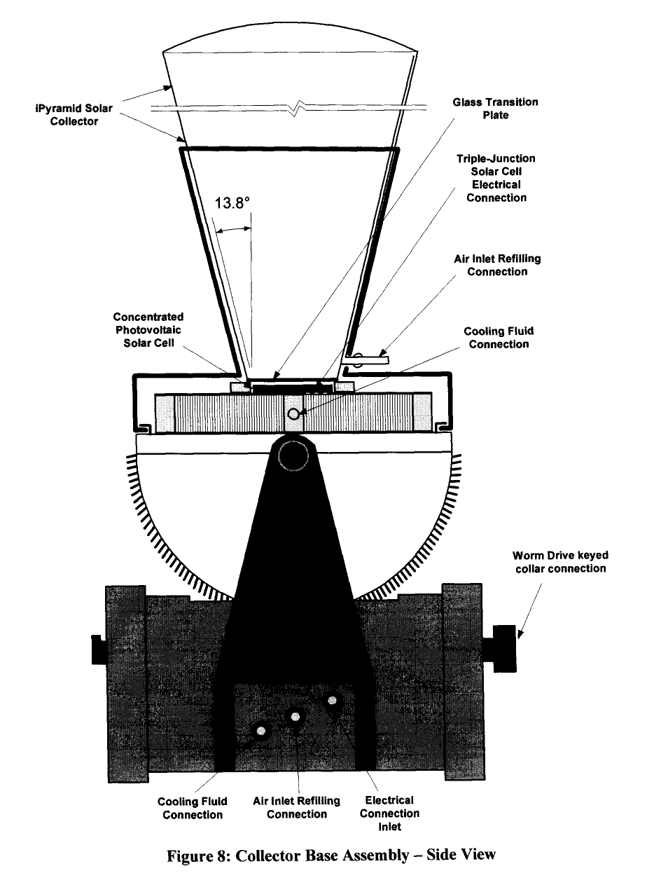

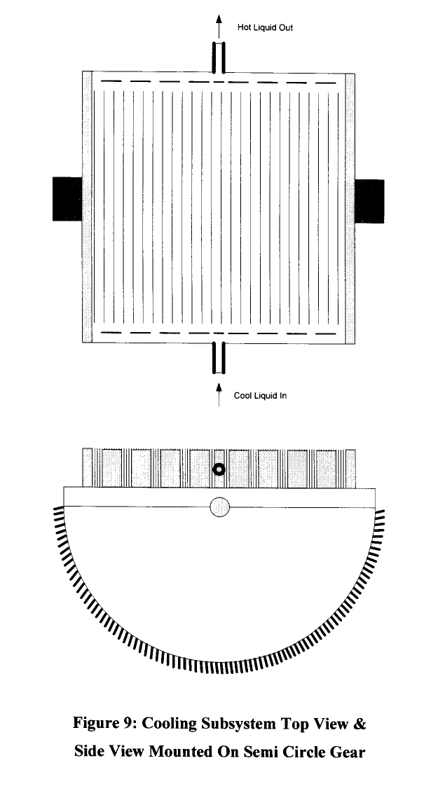

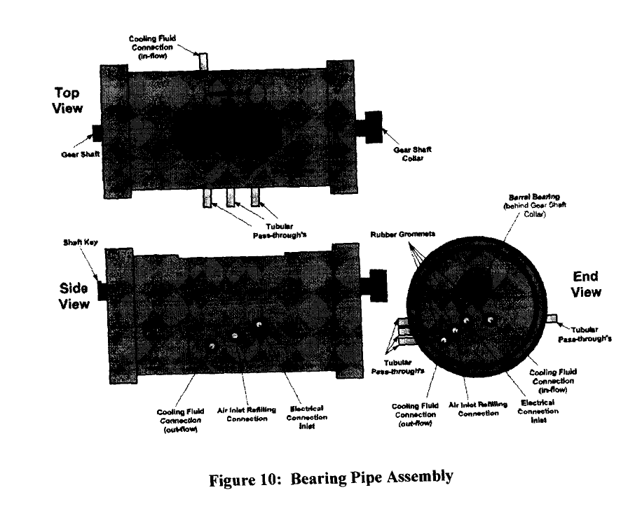

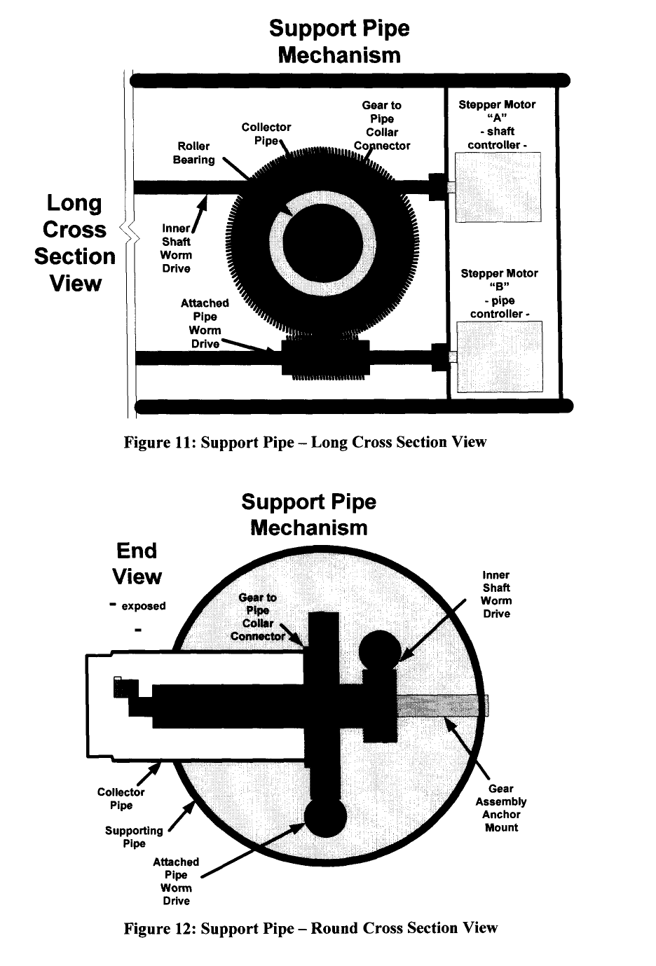

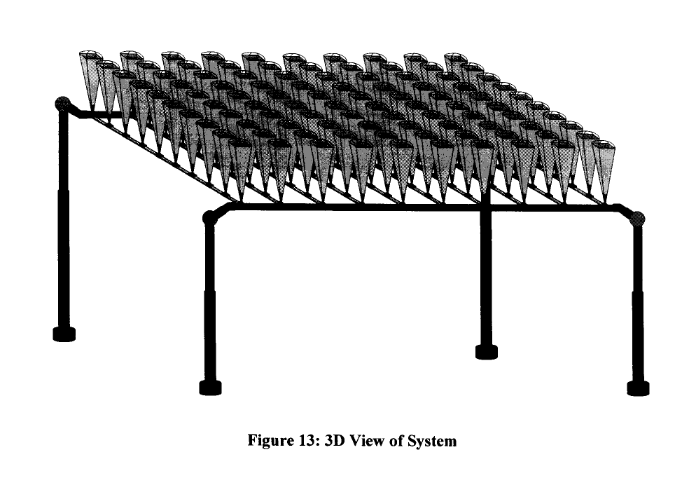

### DETAILED DESCRIPTION

1. Highly Efficient, yet Practical PV Solar System

One goal of the invention is to concentrate solar light and energy using highly reflective solar collectors in the shape of a truncated, symmetrical, inverted pyramid.

Another goal of the invention is to develop an efficient solar system that utilizes concentrated solar technology.
2. Full 180 Degrees Tracking Angle—Triple-Axis Tracking

Another goal of the invention is to achieve maximal, sun tracking amplitude and duty cycle for the array of solar energy concentrators.

Another goal of the invention is to propose a system that effectively captures solar altitude and azimuth angles to maximize the duration of the sun's exposure for photovoltaic cells.

Another goal of the invention is to design a dual-axis solar tracking system.

Another goal of the invention is to design a triple-axis solar tracking system.

Another goal of the invention is to design a solar collector, tracking the sun at the full 180 degree range without employing high precision optics equipment.

Another goal of the invention is to propose a system that converts the sunrise/sunset periods into hours usable for collecting solar energy.

Another goal of the invention is to propose a system that can automatically adjust to the seasonal migration of the sun, north and south.
3. Cost Effective Solar System

Another goal of the invention is to obtain higher energy output and more cost efficient than that of comparable solar generation systems using concentrated solar photovoltaic cells.

Another goal of the invention is to obtain energy output higher and more cost efficient than that of the solar generation systems using standard non-concentrated solar cells.

Another goal of the invention is to build an array of solar collectors utilizing inexpensive materials to minimize the energy output cost in dollars per kilowatt hour.
4. Easy to Deploy Solar System

Another goal of the invention is to design a modular structure that allows arrays of solar collectors to be installed quickly and in any required size.

Another goal of the invention is to propose a modular solar system that is easy to assemble and simple in maintenance.
5. Large-Scale Solar System

Another goal of the invention is to design a large-scale solar array for commercial applications.
6. Compact Solar System Another goal of the invention is to design a compact solar array for residential use.
7. Nano-Scale Solar System

Another goal of the invention is to propose a nano-scale solar matrix made of micro-size solar collectors in the shape of truncated inverted pyramids with nano-cells at the bottom.
8. Environmentally Friendly Solar System

Another goal of the invention is to propose a system capable of producing high efficiency energy return with minimal consumption of ground space.

Another goal of the invention is to propose a solar array elevated above ground at a height sufficient for using the land beneath for agricultural and other purposes, which will minimize the overall footprint.
9. Safe Solar System

Another goal of the invention is to build a safety-wise reliable solar system.
10. One-Way Trapping

Another goal of the invention is to design a coating for the solar energy collector that will allow the efficient collection of sun light without utilizing a tracking system.

Another goal of the invention is to suggest a method that provides a very high degree of light trapping for solar cells by restricting the escaping reflectance via total internal reflection at the collector opening. The light-trapping method is an alternative to sun tracking.

### Method to Concentrate Solar Light

A solar energy acquisition, concentration and conversion system based on an array of light concentrating collectors in the shape of inverted truncated pyramids optimized for full range sun tracking is designed for the generation of electrical power. The invention relates to solar power concentration utilizing plurality of highly reflective concentrators arranged to focus the incident light so that it directly falls on the photovoltaic solar cell, which is integrally incorporated into the concentrator at its bottom. The array of concentrated photovoltaic cells tracks the trajectory of the sun to maximize the cell exposure to the solar radiation.

Solar light concentrating arrays enable the cost-effective utilization of high-efficiency solar cells while providing the utmost energy output, minimizing the environmental impact on the land, and eliminating possible hazards.

The author of this paper addresses the demand for a highly efficient solar concentration system with emphasis on unsurpassed sun tracking capability combined with cost and manufacturing gains. Among other advantages, an embodiment of the present invention delivers low-cost mass production of concentrators and precise triple-axis tracking. Suggested array designs emphasize lightweight, effortless scalability, and ease of manufacture and assembly. The method of solar energy concentration of the present invention requires much less accuracy and precision in construction and maintenance when compared to techniques employing a parabolic trough, dish mirrors and lenses. While lenses/mirrors-based systems fulfill their function of concentrating sun energy, they have obvious drawbacks being bulky, expensive and involving complicated high-hazard concentration methods. The suggested method provides a simple, inexpensive, efficient, practical, and non-hazardous concentration.

As a consequence of the foregoing situation, there has existed a longstanding need for a new and improved sun concentration technique and the provision of such a technique is a stated objective of the present invention.

### General Description of the System

The system comprises the following elements:
Solar collectors mounted on pipes
Horizontally aligned parallel rows of collector-bearing pipes rotating along their axes
Two supporting pipes elongated across the front and back of the rows of collector-bearing pipes
Vertical pipes holding horizontally positioned collector-bearing and supporting pipes
Mechanisms controlling the sun tracking motion of the pipes and collectors The said mechanism includes:
   Mechanism, installed inside (or outside) of the collector-bearing pipes, that actuates solar collectors for a tilting motion
   Mechanism installed inside the back supporting pipe that imparts rotational motion to the collector-bearing pipes
   Mechanism installed inside the vertical pipes that moves the said pipes up and down
   Electronic devices that control the sun tracking mechanism
   Cooling device

The solar concentration assembly represents parallel rows of lightweight pipes with movably mounted solar collectors of an inverted, truncated-pyramid shape with a square top aperture.

Each row is referred to as a solar sub-array. The horizontally aligned sub-arrays of collector-bearing pipes rotate at specific angles to achieve maximal sun tracking. The number of sub-arrays deployed depends on the site requirements. The modular arrangement allows arrays to be installed quickly and in varying sizes, depending on the energy output to be obtained per square meter of land, and utilization of the land under the array.

The front of the rectangular assembly is pointed towards the azimuth and has supporting vertical pipes that shift shorter or longer than those of the rear side, so that the tilt of the assembly forms a preset angle in relation to the azimuth. Collectors and assembly tilt at angles targeted to direct collectors towards the sun's rays at 90 degrees. The tilt of the assembly depends on its geographical location and the seasonal migration of the sun.

The structural frame of the assembly is constituted from the collector-bearing pipes, disposed perpendicular to the supporting pipes that extend from one end of the array to the other. Each collector-bearing pipe is mounted on two vertical pipes, the front vertical pipe being shorter or longer than the rear to tilt the assembly at an angle optimal for sun tracking. An alternative constructional arrangement allows two vertical pipes, front and rear, to support several rows of pipes. The lower side of the assembly facing the azimuth is defined as the front side.

A tubular center support shaft can be extended in the middle and along the longer side of the structure, parallel to the supporting pipes. The collector-bearing pipes are extended through roller bearings mounted into apertures in the shaft walls, said bearings allowing for smooth rotation of the pipes inside the shaft. The holding vertical support mounted to the middle of the center support shaft is comprised of two pipes that telescope into each other by a sliding motion. The top pipe is attached to the middle of the center support shaft. The bottom pipe is dug into and rises above the ground about two feet, which allows bringing the assembly down for maintenance or during a storm.

An array can be constituted by several structures as above, spaced from each other, each structure being mounted on four vertical pipes attached to the junction of the outermost bearing pipes and supporting pipes.

Each solar collector, through reflection, concentrates sun light onto a photovoltaic cell installed at the collector's bottom for direct conversion of the sun's energy to electricity. The cooling function is accomplished by the heat sink disposed in thermal communication with the cell such that the heat generated during the sun's exposure hours is drawn from the cell and transferred to said heat sink.

The efficiency of the solar energy concentration system is defined as the ratio between the electric power generated by the photovoltaic cell as conversion product and the total solar energy incident on the cell surface.

The collectors can be produced by the utilization of generally-used, non-expensive materials and cooling agents, and by simple production technology. The system is easy to assemble and minimal in maintenance.

The assembly can be designed for large, small or nano scale deployment and can be anchored to the ground or to a rooftop. The large-scale assembly should be elevated enough to allow people and vehicles to pass beneath if so desired. A small scale embodiment does not provide a tracking mechanism and is implemented as an array of small- or micro-size systems covered with one-way film that prevents sun rays from escaping outside of the systems.

### Full 180 Degree Tracking—Triple-Axis Tracking

The system is capable of capturing light rays from any angle while tracking the sun up to 180 degrees. The full sun tracking angle is obtained by a combination of linear, oscillating and rotary motions of system components along the x-y-z-axis, which allows the collectors to constantly capture the sun's rays across the full 180 degree angle. Deployment of sub-arrays and continuous angle-varying tracking are targeted at directing the collectors towards the sun at 90 degrees, with the top aperture perpendicular to the sun's rays (±5 degrees deviation is allowed).

The system utilizes linear and rotary motions to maximize the tracking angles. Collectors tilt in two planar planes: perpendicular to the track of the pipe's rotation and in its direction longitudinally aligned to the pipe. Each collector tilts front and back to a maximum of 90 degrees away from its vertical position, until it touches the pipe. The front-back motion of collectors along their pipes is imparted by the mechanism installed in the pipes and engaged with the collector's base implemented as a semi-gear. A mechanism inside the back supporting pipe imparts rotational movement to the collector-bearing pipe causing collectors to move across the pipe's longitudinal axis.

Collector-bearing pipes are interconnected by two supporting pipes running across the front and rear of the array. Collector-bearing pipes rotate around their longitudinal axes, 90 degrees in both directions, tracing complete trajectory of 180 degrees. Each pipe rotates to up to 90 degrees in one direction, and then returns to a right angle position, and starts rotation in the opposite direction. A mechanism inside supporting pipes activates rotation of the collector-bearing pipes, which, in turn, imparts left-right motion to collectors. The collectors are maintained in perpendicular position to the sun rays while the sun's trajectory is tracked. At sunrise, an internal axis of the collector is horizontal to the ground pointing to the east, returns to its upright position at midday, and starts tilting to the west to reach a horizontal position at sunset.

By the above means, collectors tilt along the X- and Y-axis, while the collector-bearing pipes rotate along Y-axis. In addition, the assembly is shifted up and down along the vertical Z-axis by means of raising/lowering vertical pipes that support the assembly. Axes X, Y and Z are perpendicular to each other.

The up and down shift of the vertical pipes provides a precise inclination of the collector plane required to compensate for the loss of the sun rays that would occur at sunrise and sunset when the collector reaches the maximum of its longitudinal inclination, resting completely on its bearing pipe. Without collector plane inclination, when the collector-bearing pipe is horizontal to the ground, the collector positioned closer to the side facing the azimuth will partially obstruct sunrays for the collector behind it. Consequently, the collector positioned further away from the sun will only track the sun to a maximum of 90 degrees minus half the internal angle of the system. Internal angle is defined as an angle between two long sides of the pyramid facet.

To compensate for the missing angle and achieve a full 90 degree tracking on each side, the vertical pipes are shifted up and down, thus inclining the collector plane, allowing collectors to move up to a predefined degree above and below Y-axis. The value of said degree is determined to set a ray entrance angle to 90 degree. For example, during sunset the west vertical pipe is shifted shorter while the east vertical pipe is elongated in order for the west collectors not to obstruct sun for the east collectors. During sunrise the east vertical pipe is shifted shorter while the west vertical pipes are elongated in order for the east collectors not to block sun rays from the west collectors. The movable vertical pipes add approximately 20% in hours of useful time to the system.

Each vertical support of the assembly is constituted of pipes that telescope into each other by a sliding motion (or hydraulics). The top pipe is attached to the telescopic extending pipe stretching out from the corner frame of the collector plane formed by the outmost collector-bearing and supporting pipes. All vertical pipes can retract into the ground, which allows lowering the entire assembly down to ground level for maintenance or during a storm.

The rectangular structure (collector plane) constituted of the collector-bearing and supporting pipes is connected to the holding vertical pipes by the telescopic extending pipes (hereafter referred to as “Extenders”) that allow vertical pipes to lift one side of the assembly and remain immovably perpendicular to the ground. The vertical pipes at the four corners of the assembly are connected to the extenders via pivoting means, which arrangement allows the collector plane to tilt at any angle and in any direction. The extenders are mounted at the four corners of the assembly at the points where the outmost bearing pipe and supporting pipe meet perpendicular to each other. 135 degree angles are formed on either side of the extender: between the extender and the adjacent supporting pipe, and between the extender and the adjacent collector bearing pipe. The extenders compensate for the stretching effect formed by inclining the collector plane of the assembly.

The extender is constituted of: telescopically mated internal and external pipes, the internal pipe being fixed at the joint of the outermost bearing pipe and supporting pipe; a hinge pivotably mounted on the external pipe and attached to the top of the vertical pipe holding the assembly; and a spring load that pushes the stretched internal pipe back to its inward position within the external pipe.

The extenders are vertically and horizontally pivotable with respect to the vertical pipes to enable pivoting adjustment of the collector plane relative to the ground.

The above means enable the collector plane to trace out a circular trajectory in relation to a reference point located in the center of the collector plane.

The above components, combined together, provide a three-dimensional tilt mechanism that enables the collector plane to rotate, pivot, and incline laterally and forwards or backwards.

### Dual-Axis Tracking

A dual axis-implementation wherein an array is placed above the ground can be applied for sites where triple-tracking is not required. The collector plane can be placed horizontally to the ground or at a fixed vertical position of an array with a fixed optimal angle of tilt towards azimuth. Relatively short vertical pipes (e.g. an array installed at an elevation of 1 foot) that do not move up and down hold supporting and rotatable collector-bearing pipes with movably mounted solar collectors, as described in the section above. The assembly is inclined with respect to the azimuth in such a way that sunrays enter the collector parallel to the collector's internal axis.

### Mechanism Driving Collectors

The mechanism for automatically moving the collectors through a sequence of predetermined positions is based on electrically driven gears. The incremental (half degree at a time) movement is accomplished by means of a programmable microcontroller that controls the movement of a worm drive through a stepper motor.

The worm drive spiraling inside the collector-bearing pipe is engaged with the collector's base implemented as a semi-gear and imparts the base with a longitudinal (along the length of the pipe) movement. The back and forth oscillating motion of the semi-gear base causes the collector to tilt in both directions along the length of the collector-bearing pipe.

The left and right motion is imparted to the collector by the rotational motion of its bearing pipe. A worm drive mechanism installed inside the back supporting pipe controllably rotates the collector bearing pipes which are inserted into the perforations along the length and on the inside of the back supporting pipe. The worm drive installed inside the back supporting pipe is meshed with the gear, which covers the aperture of the collector-bearing pipe. The gear turns left and right driving the pipe for rotational movement that tilts the collectors across the axis of the collector-bearing pipes. On the opposite end, the collector-bearing pipe is adjoined with, and attached so that it is rotatable to the front supporting pipe by the locator pin protruding from the center of an end cap that overlays the aperture of the pipe. A cotter pin, inserted into the locator pin, that exits the outer side of the pipe, locks the locator pin in place.

The vertical pipes holding the collector-bearing and supporting pipes are inserted into exterior vertical pipes that house a worm drive. The worm drive, controlled by a stepper motor, enables the vertical pipes to move upwardly and downwardly inside the exterior pipes.

The sun tracking subsystem sends controlled signal to all stepper motors which in turn moves the worm drives which controls the 3-dimensional movement of the all collectors.

### EXAMPLE

A solar collector is provided in the form of an inverted symmetrical, truncated, pyramid with a square aperture at its top. A collector gathers the sun's rays and through reflection concentrates them onto a concentrated photovoltaic cell installed at collector's bottom. The inverted pyramid of the collector is truncated by a horizontal plane, at a given height from the apex. For strengthening and preventing a concentration of load at the very bottom, the collector is enclosed into a supporting rigid housing. The housing of the inverted pyramid shape is made of plastic, glass, metal or other sturdy material that provides support to the collector when it tilts and under windy conditions. The height of the housing is sufficient to maintain the collector's shape if the collector is made of a non-rigid material, e.g. balloon or film.

Collectors are mounted on a rotating pipe and trace out a 180 degree trajectory following the sun, which enters the collectors always under a direct angle)(±5°. The tilt angle depends on the collector's movement along and across the axis of its pipe, and on the inclination of the facets of the collector from its longitudinal axis.

For optimum spacing between collectors while meeting the internal angle limitation, it is suggested that the collector's height is twice the side of the square aperture. The height-aperture side ratio is therefore 2:1. The distance between the tops of the collectors, positioned with facets parallel to the longitudinal axis of the pipe, is equal to one side of the top. The distance between the collectors' bottoms is twice the side of the collector's tops. With such ratio the internal angle of the collector is kept lower than 15 degrees. The lower this angle the lesser the escaping of the sun's rays by the bouncing back effect through the top opening, thus the better the concentration is. Being pointed towards the sun at all times, the collector is capable of concentrating the sun's rays onto the cell without precise focusing required for a parabolic trough or dish setup.

The ratio between the area of the top aperture and the cell area is set according to the desired concentration value. The intensity of solar energy concentration is defined as a ratio between the solar capturing area of the collector's top aperture and the area of the solar cell. The higher the difference between the top and the bottom areas of the collector is, the higher the concentration achieved. The current range of the sun concentration for the collector is 250-1000 suns. However, lower or higher concentrations can be achieved.

Collectors can be implemented as inflatable balloons, or made of glass, plastic or metal. In film/balloon implementations, walls of the collector are hollow shells held rigid by gas pressure within. Gas is pumped into the balloon via an air valve attached to the rigid housing and serving for inflating and deflating the balloon. The inflating air is supplied into a balloon through a narrow tube that constitutes one piece with the balloon and runs along and on the outside of one of its facets. The air enters the balloon's interior through an opening on the top part of the tube. The bottom part of the tube forms a branch piece, which is bent at approximately 90 degrees and protrudes through an opening on the bottom of the supporting rigid housing. The air is pumped into the tube through a hose attached to the branch piece by mating connectors. Deflation when needed (e.g. replacement or during storm), it is carried out by means of a pump connected to the valve. The pump contracts and sucks the balloon down into the rigid housing. The frame supporting the facets is foldably retractable for fitting into the rigid housing when the balloon collapses.

Inflating-deflating is controlled by electronic means that detect the onset of storm (or extremely windy) conditions and responds by signaling the pump to collapse the balloons. The inflating air is supplied into the balloon through a narrow tube that constitutes one piece with the balloon and runs along and on the outside of one of its facets. The air enters the balloon's interior through an opening on the top part of the tube. The bottom part of the tube forms a branch piece, which is bent at approximately 90 degrees and protrudes through an opening on the bottom of the supporting rigid housing, said branch piece constituting the air inlet refilling connection. Air is pumped into the tube through a hose attached to the branch piece by mating connectors, said hose running from the air inlet refilling connection on the collector-bearing pipe.

In one embodiment, each collector is mounted on its own bearing pipe. Both apertures of the pipe are covered by inserted incaps, each having a roller bearing and three openings for cooling fluid, air and electrical pipes that run through the sequence of pipes. The pipes are connected to each other by a shaft pushed through the roller bearing on the incap into the adjacent pipe, the key on one end of the said shaft being inserted into a key notch of the shaft on the adjacent pipe.

An alternative embodiment provides for one pipe bearing multiple collectors.

### Components of Collector Base

The bottom of the collector-holding housing is framed with a plastic (or metal or rubber) frame that latches into a rectangular pedestal positioned on the top plane of the semi-circular base and constituting one piece with the latter. The solar cell is attached on the top surface of the pedestal and is separated from the hot glass of the collector's bottom by walls that extend those of the pedestal and enclose the cell.

The pedestal is constituted from a rectangular compartment that serves as an enclosure for a heat sink and has a solar cell positioned on its top plane. The heat sink dissipates heat from the cell. The upwardly projecting walls extend from the periphery of the pedestal and surround the cell preventing it from touching the heated glass of the collector bottom.

The front and back radiating fins of the heat sink are covered with plates having openings with attached hoses for pumping the cooling liquid through the front radiating fins and letting the heated liquid out through the back radiating fins.

Cooling liquid circulates in the pipes as a result of pressure created by the heat that radiates from the cell. A control valve secures one-directional movement of heated liquid away from the cell. A small pump, powered by the self-generated electricity, can be added to accelerate circulation of the cooling liquid.

The pedestal is mounted on a plastic toothed semi-wheel, protruding through the slot on the top of the pipe and engaged with the worm drive spiraling along the length of the pipe. The semi-circular base of the collector is pinned through on both sides of the plastic base mounting bracket implemented as two upturned isosceles and obtuse at the top triangles connected by two straps extended from the congruent sides of the triangles and wrapping around the pipe.

The section of the pipe wall located between the two straps carries cooling fluid outlet connection, air inlet refilling connection and electrical connection inlet.

The cooling fluid intake on the heat sink is connected by a hose to the cooling fluid inlet on the pipe's wall. On the other side of the heat sink, the cooling fluid exhaust is connected by a hose to the cooling fluid outlet connection on the opposite side of the pipe's wall.

The air inlet refilling connection on the pipe's wall is connected via hose to the branch piece of the balloon protruding through an opening at the bottom of the rigid housing.

A cord connects three receiving terminals on the solar cell with the electrical connection inlet on the pipe's wall.

The cooling fluid, air refilling and electrical entries inlet into respective tubes laid inside a collector-bearing pipe and running into adjacent pipes through the openings on their incaps.

### Cone vs System

Inverted pyramids have an advantage over cones as far as the sun capturing area is concerned. The area exposed to the sun is wider with pyramidal design, given a cone with diameter of its base equal to a circle inscribed in the pyramid's base. The area of a circle is equal A=π.(d/2)², where d is the circle's diameter. The area of a square is A=d², where d is the side of the square. Using a square with a side equal 10 cm and a circle with a diameter equal 10 cm, we find the area of the square is 100 cm² while the area of the circle is 78.54 cm². Therefore, a 21.46% gain in sun capturing area is obtained with a pyramid compared to a conical design.

### Reflection

The present invention generally relates to an inexpensive method of producing a high-efficiency solar energy collection system and/or device that uses thin, highly reflective systems.

Collectors reflect and concentrate solar rays as the rays travel from the larger aperture of the collector toward its narrow end. At the narrow end, the lowest part of the reflective system is connected to a container which houses the solar cell, heat sink and cooling fluid.

The collector's inner walls are made of a highly reflective (mirror-like) material. The inner surface reflects solar energy when solar energy is incident upon the inner surface. At any given time, the collectors are positioned such that light incident on the reflective surface is reflected towards the cell at the collector's bottom. The outer walls of the system can be coated with reflective material that dissipates the excess heat away from the collector. Sun reflective coating can be applied to the pipes' outer surface to radiate heat away.

The applied method optimizes the transfer of light radiation to the target. The number of reflections throughout the sun's ray route to the cell is minimized to one reflection since multiple reflections considerably decrease the amount of energy received by the solar cell. For example, 100% of sun energy reaches the cell upon the first reflection if the reflectivity of the system surface is 1. Given the system with the same reflectivity, only 90% of sun energy will reach the cell if the rays hit it upon second reflection.

The amount of energy that is reflected and absorbed depends on the reflection coefficient of the inner surface of the collector.

### Material (Thin Film, Glass, Plastic or Metal)

In general, in some embodiments, the invention relates to a solar power concentrator that comprises reflective material (e.g., one or more types) maintained in place and shape either due to its inflexibility or by tension and disposed within the housing. The inside walls of the containers can be aluminized (or made reflective in a number of other manners).

Collector walls can be made of reflective thin film, glass, plastic, metal, or a balloon made of reflective thin film.

The collectors are covered with transparent screen to prevent rain, snow and foreign bodies from entering therein. The collector bottom is made of a transparent glass that lets the sun's rays pass through to the cell.

In most embodiments, a lower part of the collector is inserted into a rigid enclosure that constitutes approximately one quarter of the collector's height. The enclosure can be made of plastic, metal or glass. An alternative implementation allows for the provision of an inflatable film (or a balloon) completely inserted into a rigid housing. In film/balloon implementations, walls of the collector are hollow shells held rigid by helium pressure within.

A valve, through which helium is supplied, is located at the bottom edge of the collector. Helium can be pumped to the array of collectors by a central pump. The required volume of helium is calculated to be sufficient not only to hold collectors in a vertical position, but to prevent the pipes from bending downwards. Helium can be substituted by another gas suitable for the above purposes.

Light Trapping, with the Use of One-Way Film on the Collector Top.

The light trapping method utilizes one-way film that prevents the sun's rays from escaping the collector and is a simplified alternative to an automated sun tracking mechanism. This technique allows for the collecting and concentrating of solar energy without the use of motorized controls. The system comprises a dense matrix of small reflective collectors in the shape of inverted pyramids having photovoltaic cells at their bottoms. A rooftop panel filled with micro-solar collectors is positioned in a fixed direction facing the side exposed to the sun most of the day. The panel is tilted towards the sun at an optimal angle.

The top opening of the collector is covered with a glass, transparent from outside and mirror-like from inside. The highly specular, mirror-like inside of the light-trapping cover reflects about 95% of the escaping sun's rays back towards photovoltaic cell at the collector's bottom. This method allows for effective capturing of the sun's rays that do not enter the collector at a direct angle and hence tend to bounce back and escape outside of the collector.

The light-trapping method can be applied in a combination with nano-scale solar technologies. A mini-matrix of collectors can be implemented as a coating made up of the nano-size collectors covered with one-way film. The coating can be sprayed onto a flat panel mounted to the roof.

### Electronic Sun Tracking System

The automatic tracking of the sun is based on an electronically controlled apparatus for automatically directing solar collectors to the sun, regardless of location of the array on the earth, weather conditions near the array, or intensity of electromagnetic radiation from the sun, among other disruptive or interrupting factors.

The apparatus uses a GPS device to acquire the position of the sun in the sky. The apparatus includes a controller operatively coupled to the GPS device. The controller receives the azimuth and elevation angle information for the GPS. The controller will then make its calculations and sends the appropriate electronic commands to the stepper motors which control the movement of the collectors. The positioning system is mechanically or electrically coupled to the collector. Commands from the controller control the positioning of the collector. The collector is automatically directed towards the relative position of the sun to follow the travel path of the sun across the sky.

The proprietary software inputs date and time of the array location into a GPS device, which translates that data into azimuth and elevation angles of the sun and sends their values to the proprietary controller. The controller uses the information obtained from the GPS to determine the angle of inclination for the array at any given time. The controller translates the received parameters into commands sent to the stepper motors, which activate assembly for the tilting motion.

### Cooling Means

Cooling means are provided for maintaining the solar cells at a constant temperature allowing the cell to operate at its highest efficiency.

Heat generated from the solar cell is absorbed through conduction and then dissipated by means of a heat sink, which is in thermal contact with the cell. The cooling liquid passes through the heat sink by means of a transmittal pipeline which is placed inside the supporting pipes and connected to the heat sink by means of a small tube. The heat sink dissipates heat from the solar cell positioned on the pedestal top plate. Two hoses, which supply/withdraw the circulating cooling liquid to/from the cell, exit from the front and back plates covering the radiating fins of the heat sink.

The cooling liquid is supplied to/removed from the chamber through connecting pipes and circulates in the pipes as a result of pressure created by heat that radiates from the cell. A control valve secures one-directional movement of the heated liquid away from the cell. A small pump powered by the self-generated electricity can be added to accelerate circulation of the cooling liquid.

### Environment

Environmental impact of the system is minimal generating no by-products. In solar photovoltaic technology the solar radiation falling on a solar cell is converted directly into electricity without any environmental pollution.

A mesh of pipes that constitutes the large-scale assembly can be installed over farm lands which can be utilized at or near their full capacity. The assembly will obstruct a very insignificant percent of sun's rays from hitting the ground.

The concentrating solar collector of the present invention will not start fires in nearby flammable materials. If the concentrator is pointed toward the sun, the solar energy target is deep inside the device so that it poses no danger for servicing personnel, and the bright rays do not strike nearby flammable objects. If the concentrator is pointed away from the sun, it does not concentrate the light.

1. A solar light concentrator in the shape of an inverted pyramid (hereafter referred to as “Collector”) with a light reflective (mirror-like) surface on the inside walls, with the large top opening of the collector pointed towards the sun. Concentrating the sun's light as it is reflected through the larger opening of the collector onto the high-concentration photovoltaic solar cell, (hereafter referred to as “Solar cell”) placed at the narrow end of the collector, for generating electricity from the concentrated solar light; said concentrator comprising:
Lightweight inverted, symmetrical, truncated pyramid with highly reflective inner surfaces, for receiving sunrays at a large top square opening and concentrating the sunrays by reflection to the narrow end where a concentrated photovoltaic solar cell is disposed; said pyramid made of (but not limited to) an inflatable lightweight reflective film which takes the shape of an inverted pyramid (e.g. balloon filled with helium), constructed from glass, plastic, metal or foil.
A concentrated photovoltaic solar cell placed under the glass bottom (can be made of other transparent materials) of the pyramid and directly converting concentrated solar energy into electrical energy;
A rigid holder of inverted pyramid shape made of plastic, glass, metal or other sturdy material that provides support to the collector when it tilts and under windy conditions; the height of said holder may vary, and is sufficient to maintain the collector's shape if the collector is made of a non-rigid material, e.g. balloon or film; the bottom of said holder being framed with a frame that latches into a rectangular pedestal;
A pyramid as above made of an inflatable film (or a balloon) with hollow shells held rigid by helium pressure within, said shells form the pyramid's walls, completely inserted into a rigid holder;
A pedestal constituted from a rectangular compartment that serves as an enclosure for a heat sink and has a solar cell positioned on its top plane; said pedestal being mounted on the top plane of a semi-circular base;
A semi-circular base implemented as a plastic toothed semi-wheel that protrudes through the slot on the top of the collector-bearing pipe and is engaged with the worm drive spiraling along the length of the pipe for tilting the collector longitudinally in relation to the pipe that holds it.
A transparent screen covering the top opening of the pyramid to protect it from rain, snow and foreign bodies;

2. Material kept in the shape of aforementioned pyramid by helium (or helium-like) gas pressure to form the walls of the said pyramid; reflective material comprising an inner surface of the pyramid having a large opening at its top serving as an inlet for the sun's rays reflected by the said reflective material when the sun light is incident upon the inner surface; and a holder comprising a rigid structure and having a shape of an inverted, truncated pyramid, within which the reflective material is disposed; the holder made of (but not limited to) plastic, metal or glass.

3. The solar power concentrator of claim 2 wherein the inner surface of the reflective material may be aluminized.

4. The solar power concentrator of claim 2 wherein the reflective material may comprise a plastic or poly film or laminate.

5. The solar power concentrator of claim 2 wherein the reflective material may comprise foil or laminate.

6. The solar power concentrator of claim 2 wherein the reflective material may comprise a polyester film or laminate.

7. The solar power concentrator of claim 2 wherein the polymer film may comprise ethylene or polytetrafluoroethylene.

8. The solar power concentrator of claim 2 wherein the outward pressure in the interior space is created by gas supplied to and maintained in the interior space.

9. The solar power concentrator of claim 2 wherein the reflective material may comprise a film.

10. The solar power concentrator of claim 2 wherein the reflective material may comprise a balloon.

11. The solar power concentrator of claim 2 wherein one-way light-trapping material covering the concentrator's top aperture reflects escaping sun rays that enter the collector at an indirect angle (and hence tend to bounce back outside of the collector) back towards photovoltaic cell at the collector's bottom.

12. Cooling system including:
A heat sink disposed in thermal connection with the solar cell such that heat generated during sun exposure hours is drawn from the cell and transferred to said heat sink;
A cooling liquid circulating in the conveying pipes as a result of pressure created by the heat that radiates from the solar cell;
A hose exiting from the front plate covering radiating fins of the heat sink for supplying the cooling liquid to the heat sink;
A hose exiting from the back plate covering radiating fins of the heat sink for withdrawing the heated cooling liquid from the heat sink;
Connecting pipes through which the cooling liquid is supplied to/removed from the chamber enclosing the heat sink;
A control valve that secures one-directional movement of the heated liquid away from the solar heat sink;
A pump accelerating circulation of the cooling liquid.

13. A plurality of highly reflective solar concentrators, according to claim 1, arranged to focus the incident sunlight so that it directly falls on the photovoltaic solar cells integrally incorporated into the concentrators at their bottoms; said array of solar concentrators tracking the trajectory of the sun to maximize the cell exposure to the solar radiation.

14. Large-scale solar energy concentration array of movable pipes and solar concentrators, whose motion along three axis allows triple-axis tracking of the sun at up to 180 degrees and directing solar concentrators towards the sun at 90 degrees, said array being intended for generating electrical power for industrial applications and comprised of:
Horizontally aligned parallel rows of lightweight pipes (hereafter referred to as solar sub-arrays) with movably mounted solar concentrators according to claim 1; said pipes (hereafter referred to as collector-bearing pipes) having their back apertures covered with gears and being inserted into a back supporting pipe in such a manner that the said gears are engaged with the worm drive inside the back supporting pipe for setting the collector-bearing pipes to rotate about their axis;
the said collector-bearing pipes being rotatably attached to the front supporting pipe by the locator pin protruding from the center of an end cap that overlays the front aperture of the collector-bearing pipe;
Solar concentrator according to claim 1, movably mounted on a collector-bearing pipe, having inside, a worm drive engaged with the concentrator's base implemented as a semi-gear for tilting the concentrator front and back along the collector-bearing pipe, whose rotation about its axis imparts additional, left-right, motion to the concentrator across the axis of the collector-bearing pipe;
Front and back supporting pipes elongated across the front and back of rows of the collector-bearing pipes, and extending from one end of the array to the other in a direction perpendicular to the collector-bearing pipes in such a manner that together the supporting and collector-bearing pipes form a rectangular structure, with the front side facing the azimuth and tilted downwards towards the azimuth by means of raising/lowering vertical pipes that hold the supporting and collector bearing pipes;
Vertical supports enabling the collectors to move along the third axis and, said vertical supports holding each (or several) of the collector-bearing pipe(s) at the front and back, and holding the supporting pipes at the four corners of the assembly; said vertical supports comprised of inner vertical pipes inserted into outer vertical pipes that house worm drives imparting upward and downward motion to the vertical pipes; said worm drives being controlled by a stepper motor;
Telescopic extenders connected via pivoting means with the vertical supports disposed on the four corners of the assembly; said extenders being constituted of: telescopically mated internal and external pipes, the internal pipe being fixed at the joint of the outermost bearing pipe and supporting pipe; a hinge pivotably mounted on the external pipe and attached to the top of the vertical support holding the assembly; and a spring positioned inside the external pipe and against the internal pipe for pushing the stretched internal pipe back to its inward position within the external pipe; said extenders are vertically and horizontally pivotable with respect to the vertical pipes to enable selective vertical and horizontal pivoting adjustment of the collector plane relative to the ground;
Mechanism controlling sun tracking motion of the pipes and collectors, said mechanism including:
Mechanism, installed inside (or outside) of the collector-bearing pipes, for actuating solar collectors for a tilting motion
Mechanism installed inside the back supporting pipe that imparts rotational motion to the collector-bearing pipes
Mechanism installed inside the vertical pipes that moves the said pipes up and down
Stepper motors that actuates incremental motion of the worm drives
Electronic devices that control the sun tracking mechanism, said devices being based on the GPS, which translates latitude, longitude, date and time of the location into azimuth and elevation angles of the sun and sends their values to the proprietary controller; said controller using this information to determine the angle of inclination for the array and translating the received parameters into commands sent to the stepper motors, which activate the tilting motion for the assembly.

15. Solar energy concentration array according to claim 14 for dual-axes tracking, wherein the array is insignificantly elevated above the ground and is tilted at a fixed angle towards azimuth, optimal for capturing sunrays, said array having relatively short vertical pipes that do not move up and down and hold supporting pipes and rotatable collector-bearing pipes with movably mounted solar collectors, as described in the claim 14.

16. A solar collector comprising:
a) an inverted, symmetrical, truncated pyramid, said pyramid having a top opening, a narrow end and an inner light-reflective surface;
b) a solar cell positioned at said narrow end of said pyramid; and
c) a cover placed over said top opening; said cover having:
an outer surface comprising a transparent material to allow solar radiation to enter said pyramid, and
an inner surface comprising a reflective material to trap solar radiation within said pyramid.

17. A small-scale solar energy concentration system for generating electrical power for residential use, said system comprising a dense matrix of the solar collectors of claim 16.

18. A panel filled with the solar collectors of claim 16, said panel positioned in a fixed direction facing the side exposed to the sun most of the day and tilted towards the sun at an angle optimal for concentration of the sun's rays onto said solar cell disposed at the bottom of said collector.

19. A mini-matrix of solar collectors comprising nano-sized solar collectors of claim 16.
